(19) United States
(12) Patent Application Publication
(10) Pub. No.: US 2006/0019033 A1
(43) Pub. Date: Jan. 26, 2006

(54) Plasma treatment of hafnium-containing materials

(75) Inventors: Shankar Muthukrishnan, San Jose, CA (US); Rahul Sharangpani, Fremont, CA (US); Tejal Goyani, Sunnyvale, CA (US); Pravin K. Narwankar, Sunnyvale, CA (US); Shreyas S. Kher, Campbell, CA (US); Khaled Z. Ahmed, Anaheim, CA (US); Yi Ma, Santa Clara, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/167,070

(22) Filed: Jun. 24, 2005

Related U.S. Application Data
(63) Continuation-in-part of application No. 10/851,514, filed on May 21, 2004.

(51) Int. Cl. C23C 16/00

(52) U.S. Cl. 427/248.1

(57) ABSTRACT

In one embodiment, a method for forming a dielectric material is provided which includes exposing a substrate sequentially to a metal-containing precursor and an oxidizing gas to form metal oxide (e.g., HfOₓ) during an ALD process and subsequently exposing the substrate to an inert plasma process and a thermal annealing process. Generally, the metal oxide contains hafnium, tantalum, titanium, aluminum, zirconium, lanthanum or combinations thereof. In one example, the inert plasma process contains argon and is free of nitrogen, while the thermal annealing process contains oxygen. In another example, an ALD process to form a metal oxide includes exposing the substrate sequentially to a metal precursor and an oxidizing gas containing water vapor formed by a catalytic water vapor generator. In an alternative embodiment, a method for forming a dielectric material is provide which includes exposing a substrate to a deposition process to form a metal oxide layer and subsequently exposing the substrate to a nitridation plasma process and a thermal annealing process to form metal oxynitride (e.g., HfOₓN_{y}).

### CROSS-REFERFENCE TO RELATED APPLICATION

This application is a continuation-in-part of U.S. patent application Ser. No. 10/851,514, entitled “Stabilization of High-K Dielectric Materials,” filed on May 21, 2004, which is hereby incorporated by reference in its entirety.

### BACKGROUND OF THE INVENTION

### Field of the Invention

Embodiments of the invention generally relate to methods for depositing materials on substrates, and more specifically, to methods for depositing and stabilizing dielectric materials while forming a dielectric stack.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 65 nm or smaller and aspect ratios of 10 or greater are being considered. Accordingly, conformal deposition of materials to form these devices is becoming increasingly important.

While conventional chemical vapor deposition (CVD) has proved successful for device geometries and aspect ratios down to 0.15 μm, the more aggressive device geometries require an alternative deposition technique. One technique that is receiving considerable attention is atomic layer deposition (ALD). During an ALD process, reactant gases are sequentially introduced into a process chamber containing a substrate. Generally, a first reactant is pulsed into the process chamber and is adsorbed onto the substrate surface. A second reactant is pulsed into the process chamber and reacts with the first reactant to form a deposited material. A purge step is typically carried out between the delivery of each reactant gas. The purge step may be a continuous purge with the carrier gas or a pulse purge between the delivery of the reactant gases.

Atomic layer deposition processes have been successfully implemented for depositing dielectric layers, barrier layers and conductive layers. High-k dielectric materials deposited by ALD processes for gate and capacitor applications include hafnium oxide, hafnium silicate, zirconium oxide or tantalum oxide. Dielectric materials, such as high-k dielectric materials, may experience morphological changes when exposed to high temperatures (>500° C.) during subsequent fabrication processes. For example, titanium nitride is often deposited on hafnium oxide or zirconium oxide by a chemical vapor deposition (CVD) process at about 600° C. At such high temperature, the hafnium oxide or zirconium oxide may crystallize, loosing amorphousity and low leakage properties. Also, even if full crystallization of the dielectric material is avoided, exposure to high temperatures may form grain growth and/or phase separation of the dielectric material resulting in poor device performance due to high current leakage.

Therefore, there is a need for a process to form dielectric materials, especially high-k dielectric materials, which are morphologically stable during exposure to high temperatures during subsequent fabrication processes.

### SUMMARY OF THE INVENTION

In one embodiment, a method for forming a dielectric material on a substrate is provided which includes exposing the substrate sequentially to a metal-containing precursor and an oxidizing gas during an ALD process to form a metal oxide material thereon and subsequently exposing the substrate to an inert plasma process and a thermal annealing process. The inert plasma process exposes the substrate to a plasma formed from an inert gas for about 30 seconds to about 5 minutes. During the thermal annealing process, the substrate is heated to a temperature within a range from about 600° C. to about 1,200° C. for as long as 2 minutes. In one example, the inert plasma process exposes a substrate containing a metal oxide to a nitrogen-free, argon plasma for about 1 minute to about 3 minutes with a power output of about 1,800 watts. Subsequently, the substrate is thermally annealed within an annealing chamber containing oxygen for about 10 seconds to about 30 seconds at temperature within a range from about 800° C. to about 1,100° C.

Generally, the metal oxide material has a thickness within a range from about 5 Å to about 100 Å and contains hafnium, tantalum, titanium, aluminum, zirconium, lanthanum or combinations thereof. In one example, a hafnium oxide layer with a thickness of about 40 Å has a capacitance of at least about 2.4 μF/cm². In other examples, the method provides a pretreatment process to remove native oxides from the substrate surface and subsequently form a chemical oxide layer during a wet-clean process. In another example, the method provides exposing the substrate to a post deposition annealing process after depositing the metal oxide layer and prior to the inert plasma process.

In other embodiments described herein, metal oxide layers may be formed by an ALD process that sequentially exposes the substrate to an oxidizing gas and at least one metal precursor to form the metal oxide layer thereon. The oxidizing gas may contain water vapor formed by flowing a hydrogen source gas and an oxygen source gas into a water vapor generator. The metal precursor may include a hafnium precursor, a zirconium precursor, an aluminum precursor, a tantalum precursor, a titanium precursor, a lanthanum precursor or combinations thereof. In one example, a method for forming a hafnium-containing material on a substrate is provide which includes exposing the substrate to a deposition process to form a dielectric material containing hafnium oxide thereon, exposing the substrate to an inert plasma process that uses a nitrogen-free argon plasma and further exposing the substrate to a thermal annealing process within an oxygen-containing environment.

In an alternative embodiment, a method for forming a dielectric material on a substrate is provide which includes exposing the substrate to a deposition process to form a metal oxide layer thereon and subsequently exposing the substrate to a nitridation plasma process and to a thermal annealing process to form a metal oxynitride layer. The metal oxide layer is usually substantially free of silicon and may contain hafnium, tantalum, titanium, aluminum, zirconium, lanthanum or combinations thereof. The nitridation plasma process may last for about 1 minute to about 3 minutes with a power output within a range from about 900 watts to about 1,800 watts. The thermal annealing process heats the substrate to a temperature within a range from about 600° C. to about 1,200° C. for as long as 2 minutes. In one example, a substrate is exposed to a nitridation plasma process using a process gas containing about 50 volumetric percent (vol %) or less of nitrogen gas to form a dielectric material with a nitrogen concentration within a range from about 5 atomic percent (at %) to about 25 at %. The substrate is thermally annealed within the process chamber containing oxygen for about 10 seconds to about 30 seconds at a temperature within a range from about 800° C. to about 1,100° C.

Generally, a dielectric oxynitride material having a thickness within a range from about 5 Å to about 100 Å has a capacitance of about 2.4 μF/cm² or less. In one example, the dielectric oxynitride material with a thickness of about 50 Å has a capacitance of about 2.35 μF/cm². In some examples, the method provides pretreatment processes to remove native oxides from the substrate surface and subsequently form a chemical oxide layer during a wet-clean process. In other examples, the method provides exposing the substrate to a post deposition annealing process after depositing the metal oxide layer and prior to the nitridation plasma process.

In another embodiment, a method for forming a hafnium-containing material on a substrate is provided which includes exposing a substrate to a deposition process to form a dielectric material containing hafnium oxide thereon, exposing the substrate to a nitridation plasma process to form hafnium oxynitride from the hafnium oxide and exposing the substrate to a thermal annealing process.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of the invention and are therefore not to be considered limiting of its scope, for the invention may admit to other equally effective embodiments.

FIG. 1 illustrates a process sequence for forming a dielectric material according to one embodiment described herein;

FIGS. 2A-2C depict a substrate during various stages of the process sequence referred to in FIG. 1;

FIG. 3 graphically illustrates electrical properties of a dielectric material formed according to one embodiment described herein;

FIG. 4 illustrates a process sequence for forming a dielectric material according to another embodiment described herein;

FIGS. 5A-5C depict a substrate during various stages of the process sequence referred to in FIG. 4; and

FIGS. 6A-6B graphically illustrate electrical properties of a dielectric material formed according to one embodiment described herein.

### DETAILED DESCRIPTION OF THE PREFERRED EMBODIMENT

Embodiments of the invention provide methods for preparing dielectric materials used in a variety of applications, especially for high-k dielectric materials used in transistor and capacitor fabrication. An atomic layer deposition (ALD) process may be used to control elemental composition of the formed dielectric compounds. In one embodiment, a dielectric material or a dielectric stack is prepared by depositing a dielectric layer containing a metal oxide during on a substrate an ALD process, exposing the substrate to an inert gas plasma process while densifying the dielectric layer and subsequently exposing the substrate to a thermal annealing process. In another embodiment, a dielectric material or a dielectric stack is prepared by depositing a dielectric layer containing a metal oxide on a substrate during an ALD process, exposing the dielectric layer to a nitridation process to form a metal oxynitride from the metal oxide and subsequently exposing the substrate to a thermal annealing process.

The dielectric layers usually contain a metal oxide and may be deposited by an ALD process, a conventional chemical vapor deposition (CVD) process or a physical vapor deposition (PVD) process. The dielectric layers contain oxygen and at least one additional element, such as hafnium, tantalum, titanium, aluminum, zirconium, lanthanum or combinations thereof. For example, the dielectric layers may contain hafnium oxide, zirconium oxide, tantalum oxide, aluminum oxide, lanthanum oxide, titanium oxide, derivatives thereof or combinations thereof. In some examples, the dielectric layer is a metal oxide substantially free of silicon. Embodiments of the invention provide an ALD process that exposes the substrate sequentially to a metal precursor and an oxidizing gas to form the dielectric layer. In one example, the oxidizing gas contains water vapor formed by flowing a hydrogen source gas and an oxygen source gas into a water vapor generator.

Inert Plasma Stabilization of Dielectric Material

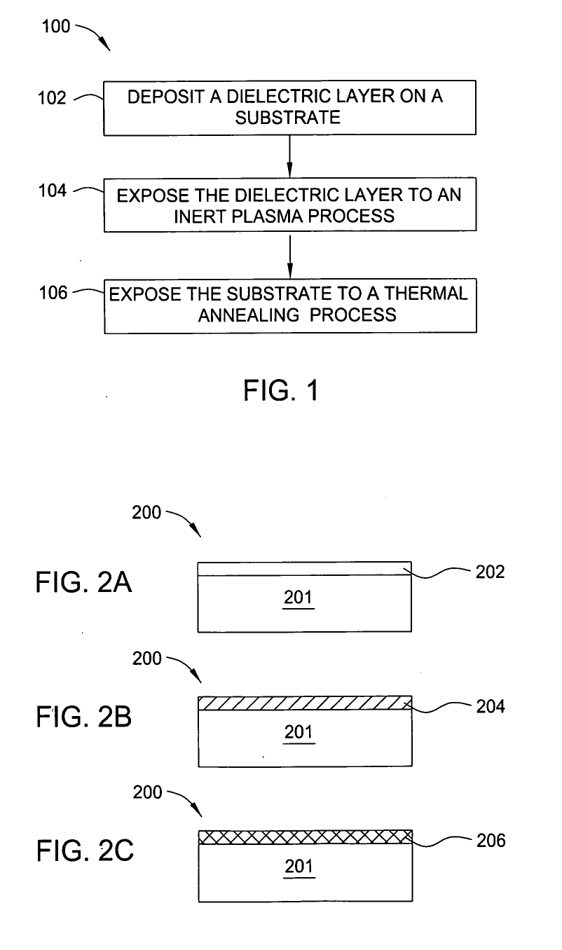

In FIG. 1, a flow chart illustrates an exemplary process 100 for forming a dielectric material, such as a metal oxide material (e.g., HfOₓ or TaOₓ). FIGS. 2A-2C correspond to process 100 to illustrate the formation of a dielectric material used in a semiconductor device, such as a transistor or a capacitor. Layer 201, containing oxide layer 202 disposed on layer 201, is exposed to an inert plasma process to form plasma-treated oxide layer 204 (FIG. 2B) that is subsequently converted to post anneal layer 206 by a thermal annealing process (FIG. 2C).

Prior to depositing oxide layer 202, layer 201 may be exposed to a pretreatment process in order to terminate the substrate surface with a preferable functional group. Functional groups that are useful prior to starting a deposition process as described herein include hydroxyls (OH), alkoxy (OR, where R=Me, Et, Pr or Bu), haloxyls (OX, where X═F, Cl, Br or I), halides (F, Cl, Br or I), oxygen radicals and aminos (NR or NR₂, where R═H, Me, Et, Pr or Bu). The pretreatment process may expose the substrate to a reagent, such as NH₃, B₂H₆, SiH₄, SiH₆, H₂O, HF, HCl, O₂, O₃, H₂O, H₂O₂, H₂, atomic-H, atomic-N, atomic-O, alcohols, amines, plasmas thereof, derivatives thereof or combination thereof. The functional groups may provide a base for an incoming chemical precursor to attach on the substrate surface. The pretreatment process may expose substrate 200 to the reagent for a period in a range from about 1 second to about 2 minutes, preferably from about 5 seconds to about 60 seconds. Pretreatment processes may also include exposing substrate 200 to an RCA solution (SC1/SC2), an HF-last solution, water vapor from WVG or ISSG systems, peroxide solutions, acidic solutions, basic solutions, plasmas thereof, derivatives thereof or combinations thereof. Useful pretreatment processes are described in commonly assigned U.S. Pat. No. 6,858,547 and co-pending U.S. patent application Ser. No. 10/302,752, filed Nov. 21, 2002, entitled, “Surface Pre-Treatment for Enhancement of Nucleation of High Dielectric Constant Materials,” and published as U.S. 20030232501, which are both incorporated herein by reference in their entirety for the purpose of describing pretreatment methods and compositions of pretreatment solutions.

In one example of a pretreatment process, a native oxide layer is removed prior to exposing substrate 200 to a wet-clean process to form a chemical oxide layer having a thickness of about 10 Å or less, such as within a range from about 5 Å to about 7 Å. Native oxides may be removed by a HF-last solution. The wet-clean process may be performed in a TEMPEST™ wet-clean system, available from Applied Materials, Inc., located in Santa Clara, Calif. In another example, substrate 200 is exposed to water vapor derived from a WVG system for about 15 seconds prior to starting an ALD process.

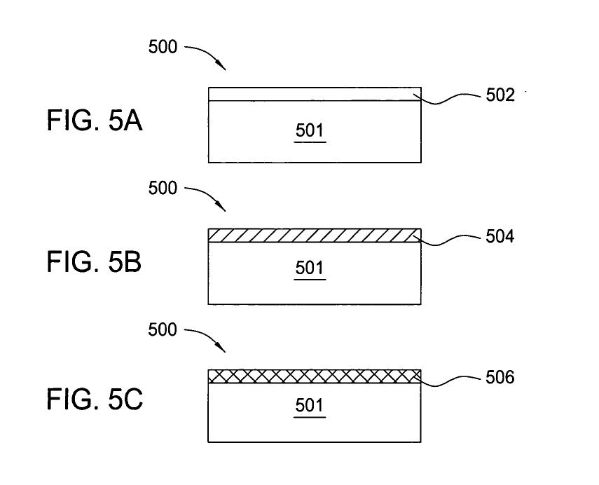

In one embodiment of process 100, oxide layer 202 is formed on layer 201, during step 402, by vapor deposition processes, such as ALD, CVD, PVD, thermal techniques or combinations thereof, as depicted in FIG. 5A. In a preferred embodiment, oxide layer 202 may be deposited by ALD processes and apparatuses as described in commonly assigned and co-pending U.S. patent application Ser. Nos. 11/127,767 and 11/127,753, both filed May 12, 2005, and both entitled, “Apparatuses and Methods for Atomic Layer Deposition of Hafnium-containing High-K Materials,” which are incorporated herein by reference in their entirety for the purpose of describing methods and apparatuses used during ALD processes. Oxide layer 202 is generally deposited with a film thickness in a range from about 5 Å to about 300 Å, preferably from about 10 Å to about 200 Å, and more preferably from about 20 Å to about 100 Å. In some example, oxide layer 202 has a thickness within a range from about 10 Å to about 60 Å, preferably from about 30 Å to about 40 Å.

Oxide layer 202 is deposited on the substrate surface and may have a variety of compositions that are homogenous, heterogeneous or graded and may be a single layer, multiple layered stacks or laminates. Oxide layer 202 is a high-k dielectric material generally containing a metal oxide. Therefore, oxide layer 202 contains oxygen and at least one metal, such as hafnium, zirconium, titanium, tantalum, lanthanum, aluminum or combinations thereof. Although some silicon diffusion into oxide layer 202 may occur from the substrate, oxide layer 202 is usually substantially free of silicon. Oxide layer 202 may have a composition that includes hafnium-containing materials, such as hafnium oxides (HfOₓ or HfO₂), hafnium oxynitrides (HfOₓN_{y}), hafnium aluminates (HfAlₓO_{y}), hafnium lanthanum oxides (HfLaₓO_{y}), zirconium-containing materials, such as zirconium oxides (ZrOₓ or ZrO₂), zirconium oxynitrides (ZrOₓN_{y}), zirconium aluminates (ZrAlₓO_{y}), zirconium lanthanum oxides (ZrLaₓO_{y}), other aluminum-containing materials or lanthanum-containing materials, such as aluminum oxides (Al₂O₃ or AlOₓ), aluminum oxynitrides (AlOₓN_{y}), lanthanum aluminum oxides (LaAlₓO_{y}), lanthanum oxides (LaOₓ or La₂O₃), derivatives thereof or combinations thereof. Other dielectric materials useful for oxide layer 202 may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). Laminate films that are useful dielectric materials for oxide layer 202 include HfO₂/Al₂O₃, La₂O₃/Al₂O₃ and HfO₂/La₂O₃/Al₂O₃.

In one embodiment, substrate 200 may be optionally exposed to a post deposition anneal (PDA) process. Substrate 200 containing oxide layer 202 is transferred to an annealing chamber, such as the CENTURA™ RADIANCE™ RTP chamber available from Applied Materials, Inc., located in Santa Clara, Calif. and exposed to the PDA process. The annealing chamber may be on the same cluster tool as the deposition chamber and/or the plasma chamber, so substrate 200 may be annealed without being exposed to the ambient environment. Substrate 200 may be heated to a temperature within a range from about 600° C. to about 1,200° C., preferably from about 600° C. to about 1,150° C., and more preferably from about 600° C. to about 1,000° C. The PDA process may last for a time period within a range from about 1 second to about 5 minutes, preferably, from about 1 minute to about 4 minutes, and more preferably from about 2 minutes to about 4 minutes. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains nitrogen and at least one oxygen-containing gas, such as oxygen. The chamber may have a pressure within a range from about 5 Torr to about 100 Torr, for example, about 10 Torr. In one example of a PDA process, substrate 200 containing oxide layer 202 is heated to a temperature of about 600° C. for about 4 minutes within an oxygen atmosphere.

In step 104, oxide layer 202 is exposed to an inert plasma process to densify the dielectric material while forming plasma-treated layer 204, as depicted in FIG. 2B. The inert plasma process may include a decoupled inert gas plasma process performed by flowing an inert gas into a decoupled plasma nitridation (DPN) chamber or a remote inert gas plasma process by flowing an inert gas into a process chamber equipped by a remote plasma system.

In one embodiment of an inert plasma process, substrate 200 is transferred into a DPN chamber, such as the CENTURA™ DPN chamber, available from Applied Materials, Inc., located in Santa Clara, Calif. In one aspect, the DPN chamber is on the same cluster tool as the ALD chamber used to deposit the oxide layer 202. Therefore, substrate 200 may be exposed to an inert plasma process without being exposed to the ambient environment. During the inert plasma process, the oxide layer 202 is bombarded with ionic argon formed by flowing argon into the DPN chamber. Gases that may be used in an inert plasma process include argon, helium, neon, xenon or combinations thereof.

If any nitrogen is co-flowed with the inert gas, the nitrogen will nitridize the dielectric material, such as converting metal oxides into metal oxynitrides. Trace amounts of nitrogen that likely exist in a DPN chamber used for nitridation process may inadvertently combine with the inert gas while performing a plasma process. The inert plasma process uses a gas that contains at least one inert gas and no nitrogen (N₂) or only a trace amount of nitrogen. In one embodiment, the nitrogen concentration due to residual nitrogen within the inert gas is about 1 vol % or less, preferably about 0.1% or less, and more preferably about 100 ppm or less, for example, about 50 ppm. In one example, the inert plasma process comprises argon and is free of nitrogen or substantially free of nitrogen. Therefore, the inert plasma process increases the stability and density of the dielectric material, while decreasing the equivalent oxide thickness (EOT) unit.

The inert plasma process proceeds for a time period from about 10 seconds to about 5 minutes, preferably from about 30 seconds to about 4 minutes, and more preferably, from about 1 minute to about 3 minutes. Also, the inert plasma process is conducted at a plasma power setting within a range from about 500 watts to about 3,000 watts, preferably from about 700 watts to about 2,500 watts, and more preferably from about 900 watts to about 1,800 watts. Generally, the plasma process is conducted with a duty cycle of about 50% to about 100% and a pulse frequency at about 10 kHz. The DPN chamber may have a pressure within a range from about 10 mTorr to about 80 mTorr. The inert gas may have a flow rate within a range from about 10 standard cubic centimeters per minute (sccm) to about 5 standard liters per minute (sim), preferably from about 50 sccm to about 750 sccm, and more preferably from about 100 sccm to about 500 sccm. In a preferred embodiment, the inert plasma process is a nitrogen free argon plasma produced in a DPN chamber.

In another embodiment, the process chamber used to deposit oxide layer 202 is also used during an inert plasma process to form plasma-treated layer 204 without transferring substrate 200 between process chambers. For example, a remote argon plasma is exposed to oxide layer 202 to form plasma-treated layer 204 directly within a process chamber configured with a remote-plasma device, such as an ALD chamber or a CVD chamber. Other inert plasma processes to form plasma-treated layer 204 are contemplated, such as laser annealing substrate 200.

In step 106, substrate 200 is exposed to a thermal annealing process. In one embodiment, substrate 200 is transferred to an annealing chamber, such as the CENTURA™ RADIANCE™ RTP chamber available from Applied Materials, Inc., located in Santa Clara, Calif., and exposed to the thermal annealing process. The annealing chamber may be on the same cluster tool as the deposition chamber and/or the nitridation chamber, such that substrate 200 may be annealed without being exposed to the ambient environment. Substrate 200 may be heated to a temperature within a range from about 600° C. to about 1,200° C., preferably from about 700° C. to about 1,150° C., and more preferably from about 800° C. to about 1,000° C. The thermal annealing process may last for a time period within a range from about 1 second to about 120 seconds, preferably, from about 2 seconds to about 60 seconds, and more preferably from about 5 seconds to about 30 seconds. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains nitrogen and at least one oxygen-containing gas, such as oxygen. The chamber may have a pressure within a range from about 5 Torr to about 100 Torr, for example, about 10 Torr. In one example of a thermal annealing process, substrate 200 is heated to a temperature of about 1,050° C. for about 15 seconds within an oxygen atmosphere. In another example, substrate 200 is heated to a temperature of about 1,100° C. for about 25 seconds within an atmosphere containing equivalent volumetric amounts of nitrogen and oxygen.

The thermal annealing process converts plasma-treated layer 204 to a dielectric material or post anneal layer 206, as depicted in FIG. 5C. The thermal annealing process repairs any damage caused by plasma bombardment during step 104 and reduces the fixed charge of post anneal layer 206. The dielectric material remains amorphous and may have a nitrogen concentration within a range from about 5 at % to about 25 at %, preferably from about 10 at % to about 20 at %, for example, about 15 at %. Post anneal layer 206 has a film thickness in a range from about 5 Å to about 300 Å, preferably from about 10 Å to about 200 Å, and more preferably from about 20 Å to about 100 Å. In some examples, post anneal layer 206 has a thickness within a range from about 10 Å to about 60 Å, preferably from about 30 Å to about 40 Å.

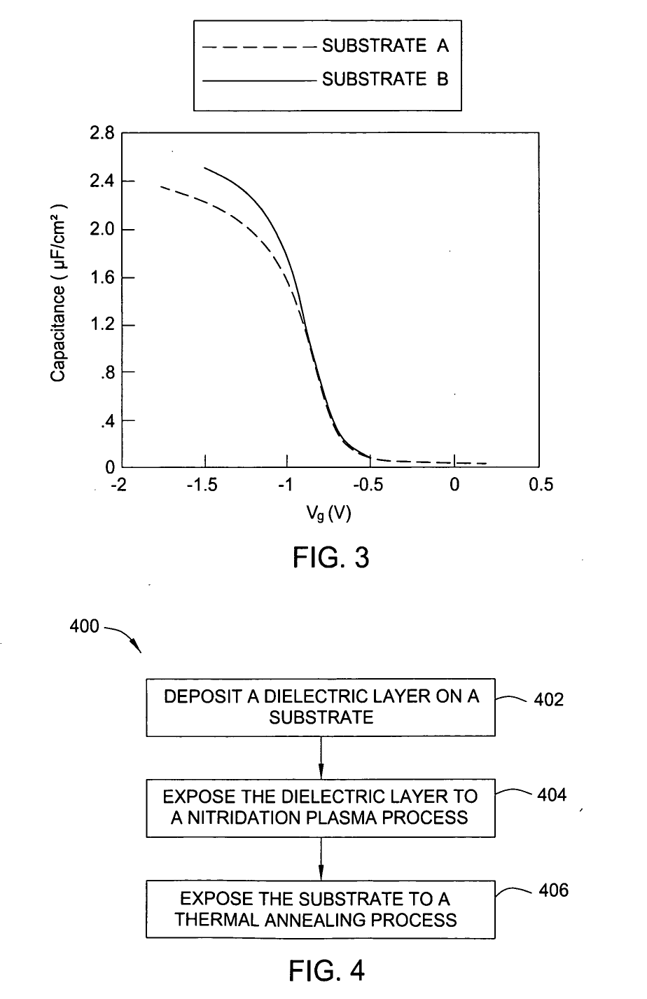

FIG. 3 graphically illustrates the capacitance versus voltage measured on two substrates each containing hafnium oxide but exposed to different plasma processes. Substrate A was exposed to a nitridation plasma process, while Substrate B was exposed to an inert plasma process. Subsequently, Substrates A and B were each exposed to a thermal annealing process at about 1,000° C., as described herein. The capacitance measured on both surfaces reveal Substrate B had a higher capacitance than Substrate A. Substrate A had a maximum capacitance of about 2.35 μF/cm², while Substrate B had a maximum capacitance of about 2.55 μF/cm².

In one embodiment, a dielectric material or post anneal layer 206 deposited by the deposition process described herein generally has a capacitance within a range from about 2 μF/cm² to about 4 μF/cm², preferably, from about 2.2 μF/cm² to about 3 μF/cm², and more preferably, from about 2.4 μF/cm² to about 2.8 μF/cm². In one example, the dielectric material is nitrogen-free or substantially nitrogen-free with a capacitance of at least about 2.4 μF/cm².

Nitrogen Stabilization of Dielectric Material

FIG. 4 illustrates an exemplary process 400 for forming a dielectric material, such as a metal oxynitride material (e.g., HfOₓN_{y} or TaOₓN_{y}). FIGS. 5A-5C correspond to process 400 to illustrate the formation of a dielectric material used in a semiconductor device, such as a transistor or a capacitor. Layer 501, containing oxide layer 502 disposed on layer 501, is exposed to a nitridation process to form oxynitride layer 504 (FIG. 5B) that is subsequently converted to post anneal layer 506 by a thermal annealing process (FIG. 5C).

Prior to depositing oxide layer 502, layer 501 may be exposed to a pretreatment process in order to terminate the substrate surface with a variety of functional groups. Functional groups useful before starting a deposition process as described herein include hydroxyls (OH), alkoxy (OR, where R=Me, Et, Pr or Bu), haloxyls (OX, where X═F, Cl, Br or I), halides (F, Cl, Br or I), oxygen radicals and aminos (NR or NR₂, where R═H, Me, Et, Pr or Bu). The pretreatment process may expose the substrate to a reagent, such as NH₃, B₂H₆, SiH₄, SiH₆, H₂O, HF, HCl, O₂, O₃, H₂O, H₂O₂, H₂, atomic-H, atomic-N, atomic-O, alcohols, amines, plasmas thereof, derivatives thereof or combination thereof. The functional groups may provide a base for an incoming chemical precursor to attach on the substrate surface. The pretreatment process may expose substrate 500 to the reagent for a period in a range from about 1 second to about 2 minutes, preferably from about 5 seconds to about 60 seconds. Pretreatment processes may also include exposing substrate 500 to an RCA solution (SC1/SC2), an HF-last solution, water vapor from WVG or ISSG systems, peroxide solutions, acidic solutions, basic solutions, plasmas thereof, derivatives thereof or combinations thereof. Useful pretreatment processes are described in commonly assigned U.S. Pat. No. 6,858,547 and co-pending U.S. patent application Ser. No. 10/302,752, filed Nov. 21, 2002, entitled, “Surface Pre-Treatment for Enhancement of Nucleation of High Dielectric Constant Materials,” and published as U.S. 20030232501, are both incorporated herein by reference in their entirety for the purpose of describing pretreatment methods and compositions of pretreatment solutions.

In one example of a pretreatment process, a native oxide layer is removed prior to exposing substrate 500 to a wet-clean process to form a chemical oxide layer having a thickness of about 10 Å or less, such as in a range from about 5 Å to about 7 Å. Native oxides may be removed by a HF-last solution. The wet-clean process may be performed in a TEMPEST™ wet-clean system, available from Applied Materials, Inc., located in Santa Clara, Calif. In another example, substrate 500 is exposed to water vapor derived from a WVG system for about 15 seconds prior to starting an ALD process.

In one embodiment of process 400, oxide layer 502 is formed on layer 501, during step 402, by vapor deposition processes, such as ALD, CVD, PVD, thermal techniques or combinations thereof, as depicted in FIG. 5A. In a one embodiment, oxide layer 502 may be deposited by ALD processes and apparatuses as described in process 100. Oxide layer 502 is generally deposited with a film thickness in a range from about 5 Å to about 300 Å, preferably from about 10 Å to about 200 Å, and more preferably from about 20 Å to about 100 Å. In some example, oxide layer 502 has a thickness within a range from about 10 Å to about 60 Å, preferably from about 30 Å to about 40 Å.

Oxide layer 502 is deposited on the substrate surface and may have a variety of compositions that are homogenous, heterogeneous or graded and maybe a single layer, multiple layered stacks or laminates. Oxide layer 502 is a high-k dielectric material generally containing a metal oxide or a metal oxynitride. Therefore, oxide layer 502 contains oxygen and at least one metal, such as hafnium, zirconium, titanium, tantalum, lanthanum, aluminum or combinations thereof. Although some silicon diffusion into oxide layer 502 may occur from the substrate, oxide layer 502 is usually substantially free of silicon. Oxide layer 502 may have a composition that includes hafnium-containing materials, such as hafnium oxides (HfOₓ or HfO₂), hafnium oxynitrides (HfOₓN_{y}), hafnium aluminates (HfAlₓO_{y}), hafnium lanthanum oxides (HfLaₓO_{y}), zirconium-containing materials, such as zirconium oxides (ZrOₓ or ZrO₂), zirconium oxynitrides (ZrOₓN_{y}), zirconium aluminates (ZrAlₓO_{y}), zirconium lanthanum oxides (ZrLaₓO_{y}), other aluminum-containing materials or lanthanum-containing materials, such as aluminum oxides (Al₂O₃ or AlOₓ), aluminum oxynitrides (AlOₓN_{y}), lanthanum aluminum oxides (LaAlₓO_{y}), lanthanum oxides (LaOₓ or La₂O₃), derivatives thereof or combinations thereof. Other dielectric materials useful for oxide layer 502 may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). Laminate films that are useful dielectric materials for oxide layer 502 include HfO₂/Al₂O₃, La₂O₃/Al₂O₃ and HfO₂/La₂O₃/Al₂O₃.

In one embodiment, substrate 500 may be optionally exposed to a post deposition anneal (PDA) process. Substrate 500 containing oxide layer 502 is transferred to an annealing chamber, such as the CENTURA™ RADIANCE™ RTP chamber available from Applied Materials, Inc., located in Santa Clara, Calif. and exposed to the PDA process. The annealing chamber may be on the same cluster tool as the deposition chamber and/or the nitridation chamber, such as that substrate 500 may be annealed without being exposed to the ambient environment. Substrate 500 may be heated to a temperature within a range from about 600° C. to about 1,200° C., preferably from about 600° C. to about 1,150° C., and more preferably from about 600° C. to about 1,000° C. The PDA process may last for a time period within a range from about 1 second to about 5 minutes, preferably, from about 5 seconds to about 4 minutes, and more preferably from about 1 minute to about 4 minutes. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains nitrogen and at least one oxygen-containing gas, such as oxygen. The chamber may have a pressure within a range from about 5 Torr to about 100 Torr, for example, about 10 Torr. In one example of a PDA process, substrate 500 containing oxide layer 502 is heated to a temperature of about 600° C. for about 4 minutes within an oxygen atmosphere.

In step 404, oxide layer 502 is exposed to a nitridation process that physically incorporates nitrogen atoms into the dielectric material to form oxynitride layer 504, as depicted in FIG. 5B. The nitridation process also increases the density of the dielectric material. The nitridation process may include decoupled plasma nitridation (DPN), remote plasma nitridation, hot-wired induced atomic-N, and nitrogen incorporation during dielectric deposition (e.g., during ALD or CVD processes). The oxynitride layer 504 is usually nitrogen-rich at the surface. The nitrogen concentration of oxynitride layer 504 may be in the range from about 5 at % to about 40 at %, preferably from about 10 at % to about 25 at %. Preferably, the nitridation process exposes the oxide layer 502 to nitrogen plasma, such as a DPN process.

In one embodiment of a nitridation process, substrate 500 is transferred into a DPN chamber, such as the CENTURA™ DPN chamber, available from Applied Materials, Inc., located in Santa Clara, Calif. In one aspect, the DPN chamber is on the same cluster tool as the ALD chamber used to deposit the oxide layer 502. Therefore, the substrate may be exposed to a nitridation process without being exposed to the ambient environment. During a DPN process, the oxide layer 502 may be bombarded with atomic-N formed by co-flowing nitrogen (N₂) and an inert or noble gas plasma, such as argon. Besides nitrogen, other nitrogen-containing gases may be used to form a nitrogen plasma, such as ammonia (NH₃), hydrazines (e.g., N₂H₄ or MeN₂H₃), amines (e.g., Me₃N, Me₂NH or MeNH₂), anilines (e.g., C₆H₅NH₂), and azides (e.g., MeN₃ or Me₃SiN₃). Gases that may be used in a plasma process include argon, helium, neon, xenon or combinations thereof.

A nitridation plasma contains a nitrogen source gas and an inert gas, such that a process gas containing a mixture of nitrogen and an inert gas may be introduced into the plasma chamber or nitrogen and an inert gas may be flowed or co-flowed into the plasma chamber. The nitrogen concentration of a nitridation plasma may be within a range from about 5 vol % to about 95 vol %, preferably from about 25 vol % to about 70 vol %, and more preferably from about 40 vol % to about 60 vol % while the remainder is an inert gas. Usually, the nitrogen concentration within the nitridation plasma is about 50 vol % or less. In one example, the nitrogen concentration is about 50 vol % and the argon concentration is about 50 vol %. In another example, the nitrogen concentration is about 40 vol % and the argon concentration is about 60 vol %. In another example, the nitrogen concentration is about 25 vol % and the argon concentration is about 75 vol %.

The nitrogen may have a flow rate within a range from about 10 sccm to about 5 slm, preferably from about 50 sccm to about 500 sccm, and more preferably from about 100 sccm to about 250 sccm. The inert gas may have a flow rate within a range from about 10 sccm to about 5 slm, preferably from about 50 sccm to about 750 sccm, and more preferably from about 100 sccm to about 500 sccm. A process gas containing nitrogen and an inert gas or flowing or co-flowing nitrogen and an inert gas may have a combined flow rate within a range from about 10 sccm to about 5 slm, preferably from about 100 sccm to about 750 sccm, and more preferably from about 200 sccm to about 500 sccm. The DPN chamber may have a pressure within a range from about 10 mTorr to about 80 mTorr. The nitridation process proceeds at a time period from about 10 seconds to about 5 minutes, preferably from about 30 seconds to about 4 minutes, and more preferably, from about 1 minute to about 3 minutes. Also, the nitridation process is conducted at a plasma power setting within a range from about 500 watts to about 3,000 watts, preferably from about 700 watts to about 2,500 watts, and more preferably from about 900 watts to about 1,800 watts. Generally, the plasma process is conducted with a duty cycle of about 50% to about 100% and a pulse frequency at about 10 kHz. In a preferred embodiment, the nitridation process is a DPN process and includes a plasma by co-flowing argon and nitrogen.

In another embodiment, the process chamber used to deposit oxide layer 502 is also used during a nitridation process to form oxynitride layer 504 without transferring substrate 500 between process chambers. For example, a nitrogen remote-plasma is exposed to oxide layer 502 to form oxynitride layer 504 directly in process chamber configured with a remote-plasma device, such as an ALD chamber or a CVD chamber. Radical nitrogen compounds may also be produced by heat or hot-wires and used during nitridation processes. Other nitridation processes to form oxynitride layer 504 are contemplated, such as annealing the substrate in a nitrogen-containing environment, and/or including a nitrogen precursor into an additional half reaction within the ALD cycle while forming the oxynitride layer 504. For example, an additional half reaction during an ALD cycle to form hafnium oxide may include a pulse of ammonia followed by a pulse of purge gas.

In step 406, substrate 500 is exposed to a thermal annealing process. In one embodiment, substrate 500 is transferred to an annealing chamber, such as the CENTURA™ RADIANCE™ RTP chamber available from Applied Materials, Inc., located in Santa Clara, Calif., and exposed to the thermal annealing process. The annealing chamber may be on the same cluster tool as the deposition chamber and/or the nitridation chamber, such that substrate 500 may be annealed without being exposed to the ambient environment. Substrate 500 may be heated to a temperature within a range from about 600° C. to about 1,200° C., preferably from about 700° C. to about 1,150° C., and more preferably from about 800° C. to about 1,000° C. The thermal annealing process may last for a time period within a range from about 1 second to about 120 seconds, preferably, from about 2 seconds to about 60 seconds, and more preferably from about 5 seconds to about 30 seconds. Generally, the chamber atmosphere contains at least one annealing gas, such as oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. Often the annealing gas contains nitrogen and at least one oxygen-containing gas, such as oxygen. The chamber may have a pressure within a range from about 5 Torr to about 100 Torr, for example, about 10 Torr. In one example of a thermal annealing process, substrate 500 is heated to a temperature of about 1,050° C. for about 15 seconds within an oxygen atmosphere. In another example, substrate 500 is heated to a temperature of about 1,100° C. for about 25 seconds within an atmosphere containing equivalent volumetric amounts of nitrogen and oxygen.

The thermal annealing process converts oxynitride layer 504 to a dielectric material or post anneal layer 506, as depicted in FIG. 5C. The thermal annealing process repairs any damage caused by plasma bombardment during step 404 and reduces the fixed charge of post anneal layer 506. The dielectric material remains amorphous and may have a nitrogen concentration within a range from about 5 at % to about 25 at %, preferably from about 10 at % to about 20 at %, for example, about 15 at %. Post anneal layer 506 has a film thickness in a range from about 5 Å to about 300 Å, preferably from about 10 Å to about 200 Å, and more preferably from about 20 Å to about 100 Å. In some examples, post anneal layer 506 has a thickness within a range from about 10 Å to about 60 Å, preferably from about 30 Å to about 40 Å.

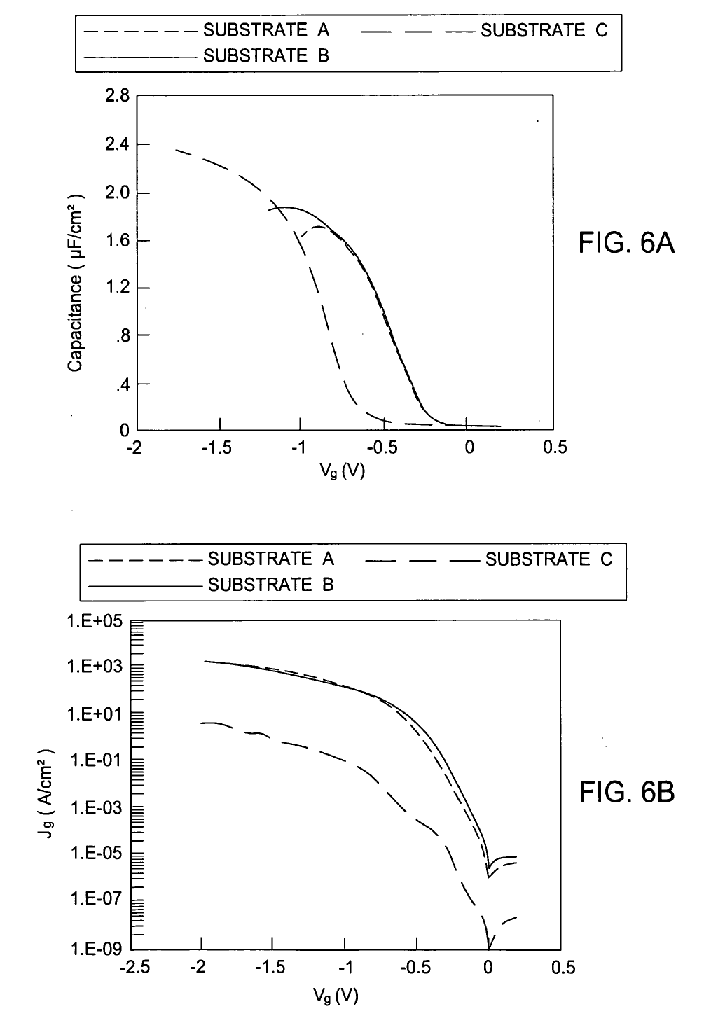

In one example, FIG. 6A graphically illustrates the capacitance versus voltage measured on three substrates each containing hafnium oxide but were not exposed or exposed to different thermal processes. Substrate A was not exposed to a plasma process or a thermal annealing process, Substrate B was exposed to a nitridation plasma process and a thermal annealing process at about 500° C. and Substrate C was exposed to a nitridation plasma process and a thermal annealing process at about 1,000° C. described herein. The capacitance measured on the surfaces reveals Substrate C has a higher capacitance than Substrate B, which has a higher capacitance than Substrate A. Substrate A has a capacitance of about 1.75 μF/cm², Substrate B has a maximum capacitance of about 1.95 μF/cm² and Substrate C has a maximum capacitance of about 2.35 μF/cm². Also, Substrate B, having already been annealed, is more thermally stable than Substrate A. Substrate A will probably crystallize upon exposure to elevated temperatures experienced in subsequent fabrication processes, while Substrate B will remain amorphous.

FIG. 6B graphically illustrates the current leakage measured on each surface to reveal Substrate C had a current density of two magnitudes lower than both Substrates A and B. Substrates A and B each had a current density greater than about 100 A/cm², while Substrate C had a current density less than about 1 A/cm².

Furthermore, Substrates B and C, having already been annealed, are more thermally stable than Substrate A, while Substrate C, having been annealed at a higher temperature, is more thermally stable than Substrate B. Substrate A will probably crystallize upon exposure to elevated temperatures experienced in subsequent fabrication processes, while Substrate C will remain amorphous. Substrate B may crystallize if the elevated temperature reaches over about 500° C.

In another embodiment, a dielectric material or post anneal layer 506 deposited by the deposition process described herein generally has a capacitance within a range from about 1.5 μF/cm² to about 3 μF/cm², preferably, from about 2 μF/cm² to about 2.7 μF/cm², and more preferably, from about 2.2 μF/cm² to about 2.5 μF/cm². In one example, the dielectric material contains nitrogen and has a capacitance of about 2.35 μF/cm² or less.

An equivalent oxide thickness (EOT) standard may be used to compare the performance of a high-K dielectric material within a MOS gate to the performance of a silicon oxide (SiO₂) based material within a MOS gate. An EOT value correlates to a thickness of the high-k dielectric material needed to obtain the same gate capacitance as a thickness of the silicon oxide material. Since (as the name implies) high-K dielectric materials have a higher dielectric constant (K) than does silicon dioxide which is about 3.9, then a correlation between thickness of a material and the K value of a material may be evaluated by the EOT value. For example, a hafnium-containing material with a K value of about 32 and a layer thickness of about 5 nm has an EOT value of about 0.6 nm. Therefore, a lower EOT value may be realized by increasing the K value of the dielectric material and by densifying the dielectric material to decrease the thickness. Therefore, a lower EOT value of a dielectric material may be cause in part by a higher K value and a thinner, denser layer due to a densification process.

Deposition Processes for Dielectric Materials

The dielectric layers described herein generally contain a metal oxide material, including oxide layers 202 and 502, and are deposited by an ALD process, a conventional CVD process or a PVD process. In one embodiment, a method for forming a dielectric material on a substrate during an atomic layer deposition process is provided which includes positioning a substrate within a process chamber and sequentially exposing the substrate to the oxidizing gas and at least one precursor, such as a hafnium precursor, a zirconium precursor, a silicon precursor, an aluminum precursor, a tantalum precursor, a titanium precursor, a lanthanum precursor or combinations thereof. Examples of dielectric material that may be formed during the deposition process include hafnium oxide, zirconium oxide, lanthanum oxide, tantalum oxide, titanium oxide, aluminum oxide, derivatives thereof or combinations thereof. The oxidizing gas containing water vapor may be formed by flowing a hydrogen source gas and an oxygen source gas through a water vapor generator. The water vapor generator has a catalyst that may contain palladium, platinum, nickel, iron, chromium, ruthenium, rhodium, combinations thereof or alloys thereof. The hydrogen source gas and/or the oxygen source gas may be diluted with an additional gas. For example, a forming gas containing about 5 vol % of hydrogen in nitrogen may be used as the hydrogen source gas. In some examples, an excess of oxygen source gas is provided into water vapor generator to provide the oxidizing gas with oxygen enriched water vapor. In other examples, the substrate is exposed to the oxidizing gas during a pre-soak process subsequent to depositing a hafnium oxide material or other metal oxide materials.

The ALD process to form metal oxide materials (e.g., oxide layers 202 and 502) is typically conducted in a process chamber at a pressure in the range from about 1 Torr to about 100 Torr, preferably from about 1 Torr to about 20 Torr, and more preferably in a range from about 1 Torr to about 10 Torr. The temperature of the substrate is usually maintained in the range from about 70° C. to about 1,000° C., preferably from about 100° C. to about 650° C., and more preferably from about 250° C. to about 500° C. A further disclosure of an ALD deposition process is described in commonly assigned U.S. patent application Ser. No. 11/127,767, filed May 12, 2005, entitled, “Apparatuses and Methods for Atomic Layer Deposition of Hafnium-containing High-K Materials,” which is incorporated herein by reference in its entirety for the purpose of describing methods and apparatuses used during ALD processes.

In one example, the hafnium precursor is introduced into the process chamber at a rate in the range from about 5 sccm to about 200 sccm. The hafnium precursor is usually introduced with a carrier gas, such as nitrogen, with a total flow rate in the range from about 50 sccm to about 1,000 sccm. The hafnium precursor may be pulsed into the process chamber at a rate in a range from about 0.1 seconds to about 10 seconds, depending on the particular process conditions, hafnium precursor or desired composition of the deposited hafnium oxide material. In one embodiment, the hafnium precursor is pulsed into the process chamber at a rate in a range from about 1 second to about 5 seconds, for example, about 3 seconds. In another embodiment, the hafnium precursor is pulsed into the process chamber at a rate in a range from about 0.1 seconds to about 1 second, for example, about 0.5 seconds. In one example, the hafnium precursor is preferably hafnium tetrachloride (HfCl₄). In another example, the hafnium precursor is preferably a tetrakis(dialkylamino)hafnium compound, such as tetrakis(diethylamino)hafnium ((Et₂N)₄Hf or TDEAH).

The hafnium precursor is generally dispensed into a process chamber by introducing a carrier gas through an ampoule containing the hafnium precursor. An ampoule may include an ampoule, a bubble, a cartridge or other container used for containing or dispersing chemical precursors. A suitable ampoule, such as the PROE-VAP™, is available from Advanced Technology Materials, Inc., located in Danbury, Conn. In one example, the ampoule contains HfCl₄ at a temperature in a range from about 150° C. to about 200° C. In another example, the ampoule may contain a liquid precursor (e.g., TDEAH, TDMAH, TDMAS or Tris-DMAS) and be part of a liquid delivery system containing injector valve system used to vaporize the liquid precursor with a heated carrier gas. Generally, the ampoule may be pressurized at a pressure within a range from about 138 kPa (about 20 psi) to about 414 kPa (about 60 psi) and may be heated to a temperature of about 100° C. or less, preferably within a range from about 20° C. to about 60° C.

The oxidizing gas may be introduced to the process chamber with a flow rate in the range from about 0.05 sccm to about 1,000 sccm, preferably in the range from about 0.5 sccm to about 100 sccm. The oxidizing gas is pulsed into the process chamber at a rate in a range from about 0.05 seconds to about 10 seconds, preferably, from about 0.08 seconds to about 3 seconds, and more preferably, from about 0.1 seconds to about 2 seconds. In one embodiment, the oxidizing gas is pulsed at a rate in a range from about 1 second to about 5 seconds, for example, about 1.7 seconds. In another embodiment, the oxidizing gas is pulsed at a rate in a range from about 0.1 seconds to about 3 seconds, for example, about 0.5 seconds.

The oxidizing gas may be produced from a water vapor generator (WVG) system in fluid communication with the process chamber. The WVG system generates ultra-high purity water vapor by means of a catalytic reaction of an oxygen source gas (e.g., O₂) and a hydrogen source gas (e.g., H₂) at a low temperature (e.g., <500° C.). The hydrogen and oxygen source gases each flow into the WVG system at a flow rate within the range from about 5 sccm to about 200 sccm, preferably, from about 10 sccm to about 100 sccm. Generally, the flow rates of the oxygen and hydrogen source gases are independently adjusted to have a presence of oxygen or an oxygen source gas and an absence of the hydrogen or hydrogen source gas within the outflow of the oxidizing gas.

An oxygen source gas useful to generate an oxidizing gas containing water vapor may include oxygen (O₂), atomic oxygen (O), ozone (O₃), nitrous oxide (N₂O), nitric oxide (NO), nitrogen dioxide (NO₂), dinitrogen pentoxide (N₂O₅), hydrogen peroxide (H₂O₂), derivatives thereof or combinations thereof. A hydrogen source gas useful to generate an oxidizing gas containing water vapor may include hydrogen (H₂), atomic hydrogen (H), forming gas (N₂/H₂), ammonia (NH₃), hydrocarbons (e.g., CH₄), alcohols (e.g., CH₃OH), derivatives thereof or combinations thereof. A carrier gas may be co-flowed with either the oxygen source gas or the hydrogen source gas and may include N₂, He, Ar or combinations thereof. Preferably, the oxygen source gas is oxygen or nitrous oxide and the hydrogen source gas is hydrogen or a forming gas, such as 5 vol % of hydrogen in nitrogen.

A hydrogen source gas and an oxygen source gas may be diluted with a carrier gas to provide sensitive control of the water vapor within the oxidizing gas during deposition processes. In one embodiment, a slower water vapor flow rate (about <10 sccm water vapor) may be desirable to complete the chemical reaction during an ALD process to form a hafnium-containing material or other dielectric materials. A slower water vapor flow rate dilutes the water vapor concentration within the oxidizing gas. The diluted water vapor is at a concentration to oxidize adsorbed precursors on the substrate surface. Therefore, a slower water vapor flow rate minimizes the purge time after the water vapor exposure to increase the fabrication throughput. Also, the slower water vapor flow rate reduces formation of particulate contaminants by avoiding undesired co-reactions. A mass flow controller (MFC) may be used to control a hydrogen source gas with a flow rate of about 0.5 sccm while producing a stream of water vapor with a flow rate of about 0.5 sccm. However, most MFC systems are unable to provide a consistent flow rate at such a slow rate. Therefore, a diluted hydrogen source gas (e.g., forming gas) may be used in a WVG system to achieve a slower water vapor flow rate. In one example, a hydrogen source gas with a flow rate of about 10 sccm and containing 5% hydrogen forming gas delivers water vapor from a WVG system with a flow rate of about 0.5 sccm. In an alternative embodiment, a faster water vapor flow rate (about >10 sccm water vapor) may be desirable to complete the chemical reaction during an ALD process while forming a hafnium-containing material or other dielectric materials. For example, about 100 sccm of hydrogen gas delivers about 100 sccm of water vapor.

The forming gas may be selected with a hydrogen concentration in a range from about 1% to about 95% by volume in a carrier gas, such as argon or nitrogen. In one aspect, a hydrogen concentration of a forming gas is in a range from about 1% to about 30% by volume in a carrier gas, preferably from about 2% to about 20%, and more preferably, from about 3% to about 10%, for example, a forming gas may contain about 5% hydrogen and about 95% nitrogen. In another aspect, a hydrogen concentration of a forming gas is in a range from about 30% to about 95% by volume in a carrier gas, preferably from about 40% to about 90%, and more preferably from about 50% to about 85%, for example, a forming gas may contain about 80% hydrogen and about 20% nitrogen.

In one example, a WVG system receives a hydrogen source gas containing 5% hydrogen (95% nitrogen) with a flow rate of about 10 sccm and an oxygen source gas (e.g., O₂) with a flow rate of about 10 sccm to form an oxidizing gas containing water vapor with a flow rate of about 0.5 sccm and oxygen with a flow rate of about 9.8 sccm. In another example, a WVG system receives a hydrogen source gas containing 5% hydrogen forming gas with a flow rate of about 20 sccm and an oxygen source gas with a flow rate of about 10 sccm to form an oxidizing gas containing water vapor with a flow rate of about 1 sccm and oxygen with a flow rate of about 9 sccm. In another example, a WVG system receives a hydrogen source gas containing hydrogen gas with a flow rate of about 20 sccm and an oxygen source gas with a flow rate of about 10 sccm to form an oxidizing gas containing water vapor at a rate of about 10 sccm and oxygen at a rate of about 9.8 sccm. In other examples, nitrous oxide, as an oxygen source gas, is used with a hydrogen source gas to form a water vapor during ALD processes. Generally, 2 molar equivalents of nitrous oxide are substituted for each molar equivalent of oxygen gas.

A WVG system contains a catalyst, such as catalyst-lined reactor or a catalyst cartridge, in which the oxidizing gas containing water vapor is generated by a catalytic chemical reaction between a source of hydrogen and a source of oxygen. A WVG system is unlike pyrogenic generators that produce water vapor as a result of an ignition reaction, usually at temperatures over 1,000° C. A WVG system containing a catalyst usually produces water vapor at a low temperature in the range from about 100° C. to about 500° C., preferably at about 350° C. or less. The catalyst contained within a catalyst reactor may include a metal or alloy, such as palladium, platinum, nickel, iron, chromium, ruthenium, rhodium, alloys thereof or combinations thereof. The ultra-high purity water is ideal for the ALD processes in the present invention. In one embodiment, to prevent unreacted hydrogen from flowing downstream, an oxygen source gas is allowed to flow through the WVG system for about 5 seconds. Next, the hydrogen source gas is allowed to enter the reactor for about 5 seconds. The catalytic reaction between the oxygen and hydrogen source gases (e.g., H₂ and O₂) generates a water vapor. Regulating the flow of the oxygen and hydrogen source gases allows precise control of oxygen and hydrogen concentrations within the formed oxidizing gas containing water vapor. The water vapor may contain remnants of the hydrogen source gas, the oxygen source gas or combinations thereof. Suitable WVG systems are commercially available, such as the Water Vapor Generator (WVG) system by Fujikin of America, Inc., located in Santa Clara, Calif. and or the Catalyst Steam Generator System (CSGS) by Ultra Clean Technology, located in Menlo Park, Calif.

The pulses of a purge gas or carrier gas, preferably argon or nitrogen, are sequentially introduced into the process chamber after each pulse of hafnium precursor, oxidizing gas or other precursor during the ALD cycle. The pulses of purge gas or carrier gas are typically introduced at a flow rate in a range from about 2 standard liters per minute (sim) to about 22 slm, preferably about 10 slm. Each processing cycle occurs for a time period in a range from about 0.01 seconds to about 20 seconds. In one example, the process cycle lasts about 10 seconds. In another example, the process cycle lasts about 2 seconds. Longer processing steps lasting about 10 seconds deposit excellent hafnium oxide films, but reduce the throughput. The specific purge gas flow rates and duration of process cycles are obtained through experimentation. In one example, a 300 mm diameter wafer requires about twice the flow rate for the same duration as a 200 mm diameter wafer in order to maintain similar throughput.

In one embodiment, hydrogen gas is applied as a carrier gas, purge and/or a reactant gas to reduce halogen contamination from the deposited materials. Precursors that contain halogen atoms (e.g., HfCl₄, ZrCl₄ and TaF₅) readily contaminate the deposited dielectric materials. Hydrogen is a reductant and will produce hydrogen halides (e.g., HCl or HF) as a volatile and removable by-product. Therefore, hydrogen may be used as a carrier gas or reactant gas when combined with a precursor compound (e.g., hafnium precursors) and may include another carrier gas (e.g., Ar or N₂). In one example, a water/hydrogen mixture, at a temperature in the range from about 100° C. to about 500° C., is used to reduce the halogen concentration and increase the oxygen concentration of the deposited material. In one example, a water/hydrogen mixture may be derived by feeding an excess of hydrogen source gas into a WVG system to form a hydrogen enriched water vapor.

In some of the embodiments described herein for depositing materials, an alternative oxidizing gas, such as a traditional oxidant, may be used instead of the oxidizing gas containing water vapor formed from a WVG system. The alternative oxidizing gas is introduced into the process chamber from an oxygen source containing water not derived from a WVG system, oxygen (O₂), ozone (O₃), atomic-oxygen (O), hydrogen peroxide (H₂O₂), nitrous oxide (N₂O), nitric oxide (NO), dinitrogen pentoxide (N₂O₅), nitrogen dioxide (NO₂), derivatives thereof or combinations thereof. While embodiments of the invention provide processes that benefit from oxidizing gas containing water vapor formed from a WVG system, other embodiments provide processes that utilize the alternative oxidizing gas or traditional oxidants while forming hafnium-containing materials and other dielectric materials during deposition processes described herein.

Many precursors are within the scope of embodiments of the invention for depositing the dielectric materials described herein. One important precursor characteristic is to have a favorable vapor pressure. Precursors at ambient temperature and pressure may be gas, liquid or solid. However, volatilized precursors are used within the ALD chamber. Organometallic compounds contain at least one metal atom and at least one organic-containing functional group, such as amides, alkyls, alkoxyls, alkylaminos or anilides. Precursors may include organometallic, inorganic or halide compounds.

Exemplary hafnium precursors include hafnium compounds containing ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials include (Et₂N)₄Hf, (Me₂N)₄Hf, (MeEtN)₄Hf, (^{t}BUC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. Preferably, hafnium precursors used during the deposition process herein include HfCl₄, (Et₂N)₄Hf or (Me₂N)₄Hf.

In an alternative embodiment, a variety of metal oxides or metal oxynitrides may be formed by sequentially pulsing metal precursors with oxidizing gas containing water vapor derived from a WVG system. The ALD processes disclosed herein may be altered by substituting the hafnium precursor with other metal precursors to form additional dielectric materials, such as hafnium aluminates, titanium aluminates, titanium oxynitrides, zirconium oxides, zirconium oxynitrides, zirconium aluminates, tantalum oxides, tantalum oxynitrides, titanium oxides, aluminum oxides, aluminum oxynitrides, lanthanum oxides, lanthanum oxynitrides, lanthanum aluminates, derivatives thereof or combinations thereof. In one embodiment, two or more ALD processes are concurrently conducted to deposit one layer on top of another. For example, a combined process contains a first ALD process to form a first dielectric material and a second ALD process to form a second dielectric material. The combined process may be used to produce a variety of hafnium-containing materials, for example, hafnium aluminum silicate or hafnium aluminum silicon oxynitride. In one example, a dielectric stack material is formed by depositing a first hafnium-containing material on a substrate and subsequently depositing a second hafnium-containing material thereon. The first and second hafnium-containing materials may vary in composition, so that one layer may contain hafnium oxide and the other layer may contain hafnium silicate. In one aspect, the lower layer contains silicon. Alternative metal precursors used during ALD processes described herein include ZrCl₄, Cp₂Zr, (Me₂N)₄Zr, (Et₂N)₄Zr, TaF₅, TaCl₅, (^{t}BuO)₅Ta, (Me₂N)₅Ta, (Et₂N)₅Ta, (Me₂N)₃Ta(N^{t}Bu), (Et₂N)₃Ta(N^{t}Bu), TiCl₄, Til₄, (ⁱPrO)₄Ti, (Me₂N)₄Ti, (Et₂N)₄Ti, AlCl₃, Me3Al, Me₂AlH, (AMD)₃La, ((Me₃Si)(^{t}Bu)N)₃La, ((Me₃Si)₂N)₃La, (^{t}BU₂N)₃La, (ⁱPr₂N)₃La, derivatives thereof or combinations thereof.

A “substrate surface,” as used herein, refers to any substrate or material surface formed on a substrate upon which film processing is performed. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein deposit hafnium-containing materials on many substrates and surfaces. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

“Atomic layer deposition” or “cyclical deposition” as used herein refers to the sequential introduction of two or more reactive compounds to deposit a layer of material on a substrate surface. The two, three or more reactive compounds may alternatively be introduced into a reaction zone of a process chamber. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. During each time delay a purge gas, such as nitrogen, is introduced into the process chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, pulsing compound B and purge gas is a cycle. A cycle can start with either compound A or compound B and continue the respective order of the cycle until achieving a film with the desired thickness. In another embodiment, a first precursor containing compound A, a second precursor containing compound B and a third precursor containing compound C are each separately pulsed into the process chamber. Alternatively, a pulse of a first precursor may overlap in time with a pulse of a second precursor while a pulse of a third precursor does not overlap in time with either pulse of the first and second precursors.

A “pulse” as used herein is intended to refer to a quantity of a particular compound that is intermittently or non-continuously introduced into a reaction zone of a processing chamber. The quantity of a particular compound within each pulse may vary over time, depending on the duration of the pulse. The duration of each pulse is variable depending upon a number of factors such as, for example, the volume capacity of the process chamber employed, the vacuum system coupled thereto, and the volatility/reactivity of the particular compound itself. A “half-reaction” as used herein is intended to refer to a pulse of precursor step followed by a purge step.

### EXAMPLES

Examples 1-10 were conducted on a CENTURA® platform containing a TEMPEST™ wet-clean system, an ALD chamber, a CENTURA® DPN (decoupled plasma nitridation) chamber and a CENTURA® RADIANCE® RTP (thermal annealing) chamber, all available from Applied Materials, Inc., located in Santa Clara, Calif. Experiments were conducted on 300 mm diameter substrates and substrate surfaces were exposed to a HF-last solution to remove native oxides and subsequently placed into the wet-clean system to form a chemical oxide layer having a thickness of about 5 Å. Several ALD chambers coupled to a water vapor generator (WVG) system are further described in commonly assigned and co-pending U.S. patent application Ser. No. 11/127,753, filed May 12, 2005, and entitled, “Apparatuses and Methods for Atomic Layer Deposition of Hafnium-containing High-K Materials,” which is incorporated herein by reference in its entirety for the purpose of describing methods and apparatuses used during ALD processes. Another useful ALD chamber is further described in commonly assigned and co-pending U.S. patent application Ser. No. 10/032,284, filed Dec. 21, 2001, entitled, “Gas Delivery Apparatuses and Method for Atomic Layer Deposition,” and published, U.S. 20030079686, which is incorporated herein by reference in its entirety for the purpose of describing methods and apparatuses used during ALD processes. The WVG system having a metal catalyst is available from Fujikin of America, Inc., located in Santa Clara, Calif. The WVG system produced the oxidizing gas containing water vapor from a hydrogen source gas (5 vol % H₂ in N₂) and an oxygen source gas (O₂).

### Example 1

### HfOₓ Deposition

A substrate containing a chemical oxide surface was placed into the ALD chamber. A hafnium oxide layer was formed during an ALD process by sequentially exposing the substrate to a hafnium precursor (HfCl₄) and an oxidizing gas containing water vapor. The ALD cycle included sequentially pulsing HfCl₄ and water vapor with each precursor separated by a nitrogen purge cycle. The ALD cycle was repeated to form a hafnium oxide layer with a thickness of about 40 Å. The substrate was transferred into the DPN chamber and exposed to an inert plasma process containing an argon plasma. The inert plasma process contained an argon flow rate of about 200 sccm for about 90 seconds at about 1,800 watts with a 50% duty cycle at 10 kHz to densify the hafnium oxide layer. The substrate was subsequently transferred to the thermal annealing chamber and heated at about 1,000° C. for about 15 seconds in an oxygen/nitrogen atmosphere maintained at about 15 Torr.

### Example 2

### HfOₓ Deposition

A substrate containing a chemical oxide surface was placed into the ALD chamber. A hafnium oxide layer was formed during an ALD process by sequentially exposing the substrate to a hafnium precursor (TDEAH) and an oxidizing gas containing water vapor. The ALD cycle included sequentially pulsing TDEAH and water vapor with each precursor separated by a nitrogen purge cycle. The ALD cycle was repeated to form a hafnium oxide layer with a thickness of about 50 Å. The substrate was transferred into the DPN chamber and exposed to an inert plasma process containing an argon plasma. The inert plasma process contained an argon flow rate of about 200 sccm for about 90 seconds at about 1,800 watts with a 50% duty cycle at 10 kHz to densify the hafnium oxide layer. The substrate was subsequently transferred to the thermal annealing chamber and heated at about 1,050° C. for about 12 seconds in an oxygen/nitrogen atmosphere maintained at about 15 Torr.

### Example 3

### TaOₓ Deposition

A substrate containing a chemical oxide surface was placed into the ALD chamber. A tantalum oxide layer is formed on the substrate surface by performing an ALD process using the tantalum precursor (TaCl₅) and water. The ALD cycle includes sequentially pulsing TaCl₅ and water vapor with each precursor separated by a nitrogen purge cycle. The ALD cycle is repeated to form a tantalum oxide layer with a thickness of about 100 Å. The substrate was transferred into the DPN chamber and exposed to an inert plasma process containing an argon plasma. The inert plasma process contained an argon flow rate of about 200 sccm for about 60 seconds at about 1,800 watts with a 50% duty cycle at 10 kHz to densify the tantalum oxide layer. The substrate was subsequently transferred to the thermal annealing chamber and heated at about 1,000° C. for about 15 seconds in an oxygen/nitrogen atmosphere maintained at about 10 Torr.

### Example 4

### ZrOₓ Deposition

A substrate containing a chemical oxide surface was placed into the ALD chamber. A zirconium oxide layer was formed during an ALD process by sequentially exposing the substrate to a zirconium precursor (ZrCl₄) and an oxidizing gas containing water vapor. The ALD cycle included sequentially pulsing ZrCl₄ and water vapor with each precursor separated by a nitrogen purge cycle. The ALD cycle was repeated to form a zirconium oxide layer with a thickness of about 60 Å. The substrate was transferred into the DPN chamber and exposed to an inert plasma process containing an argon plasma. The inert plasma process contained an argon flow rate of about 200 sccm for about 2 minutes at about 1,800 watts with a 50% duty cycle at 10 kHz to densify the zirconium oxide layer. The substrate was subsequently transferred to the thermal annealing chamber and heated at about 950° C. for about 30 seconds in an oxygen/nitrogen atmosphere maintained at about 25 Torr.

### Example 5

### HfOₓN_{y} Deposition

A substrate containing a chemical oxide surface was placed into the ALD chamber. A hafnium oxide layer was formed during an ALD process by sequentially exposing the substrate to a hafnium precursor (HfCl₄) and an oxidizing gas containing water vapor. The ALD cycle included sequentially pulsing HfCl₄ and water vapor with each precursor separated by a nitrogen purge cycle. The ALD cycle was repeated to form a hafnium oxide layer with a thickness of about 40 Å. The substrate was transferred into the DPN chamber and exposed to a nitridation plasma process to densify and incorporate nitrogen atoms within the hafnium oxide layer to form a hafnium oxynitride material. The nitridation process contained an argon flow rate of about 160 sccm and a nitrogen flow rate of about 40 sccm for about 180 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 15 Torr.

### Example 6

### HfOₓN_{y} Deposition

A substrate containing a chemical oxide surface was placed into the ALD chamber. A hafnium oxide layer was formed during an ALD process by sequentially exposing the substrate to a hafnium precursor (TDEAH) and an oxidizing gas containing water vapor. The ALD cycle included sequentially pulsing TDEAH and water vapor with each precursor separated by a nitrogen purge cycle. The ALD cycle was repeated to form a hafnium oxide layer with a thickness of about 50 Å. The substrate was transferred into the DPN chamber and exposed to a nitridation plasma process to densify and incorporate nitrogen atoms within the hafnium oxide layer to form a hafnium oxynitride material. The nitridation process contained an argon flow rate of about 160 sccm and a nitrogen flow rate of about 40 sccm for about 180 seconds at about 1,800 watts with a 50% duty cycle at 10 kHz. The substrate was subsequently transferred to the thermal annealing chamber and heated at about 1,050° C. for about 12 seconds in an oxygen/nitrogen atmosphere maintained at about 15 Torr.

### Example 7

### TaOₓN_{y} Deposition

A substrate containing a chemical oxide surface was placed into the ALD chamber. A tantalum oxide layer is formed on the substrate surface by performing an ALD process using the tantalum precursor (TaCl₅) and water. The ALD cycle includes sequentially pulsing TaCl₅ and water vapor with each precursor separated by a nitrogen purge cycle. The ALD cycle is repeated to form a tantalum oxide layer with a thickness of about 100 Å. The substrate was transferred into the DPN chamber and exposed to a nitridation plasma process to densify and incorporate nitrogen atoms within the tantalum oxide layer to form a tantalum oxynitride material. The nitridation process contained an argon flow rate of about 120 sccm and a nitrogen flow rate of about 80 sccm for about 120 seconds at about 1,800 watts with a 50% duty cycle at 10 kHz. The substrate was subsequently transferred to the thermal annealing chamber and heated at about 1,000° C. for about 15 seconds in an oxygen/nitrogen atmosphere maintained at about 10 Torr.

### Example 8

### ZrOₓN_{y} Deposition

A substrate containing a chemical oxide surface was placed into the ALD chamber. A zirconium oxide layer was formed during an ALD process by sequentially exposing the substrate to a zirconium precursor (ZrCl₄) and an oxidizing gas containing water vapor. The ALD cycle included sequentially pulsing ZrCl₄ and water vapor with each precursor separated by a nitrogen purge cycle. The ALD cycle was repeated to form a zirconium oxide layer with a thickness of about 60 Å. The substrate was transferred into the DPN chamber and exposed to a nitridation plasma process to densify and incorporate nitrogen atoms within the zirconium oxide layer to form a zirconium oxynitride material. The nitridation process contained an argon flow rate of about 100 sccm and a nitrogen flow rate of about 100 sccm for about 60 seconds at about 1,800 watts with a 50% duty cycle at 10 kHz. The substrate was subsequently transferred to the thermal annealing chamber and heated at about 950° C. for about 30 seconds in an oxygen/nitrogen atmosphere maintained at about 25 Torr.

### Example 9

### HfOₓ Deposition for FIG. 3A

A hafnium oxide layer was deposited on Substrates A and B under the identical process conditions. Substrate A was transferred into the DPN chamber and exposed to a nitridation plasma process. The nitridation process contained an argon flow rate of about 160 sccm and a nitrogen flow rate of about 40 sccm for about 180 seconds at about 1,800 watts with a 50% duty cycle at 10 kHz. Substrate B was transferred into the DPN chamber and exposed to an inert plasma process containing an argon plasma. The inert plasma process contained an argon flow rate of about 200 sccm for about 90 seconds at about 1,800 watts with a 50% duty cycle at 10 kHz to densify the hafnium oxide layer. Substrates A and B were subsequently transferred to the thermal annealing chamber and heated at about 1,000° C. for about 15 seconds in an oxygen/nitrogen atmosphere maintained at about 15 Torr.

The capacitance was measured on both surfaces to reveal Substrate B had a higher capacitance than Substrate A (FIG. 3). Substrate A had a maximum capacitance of about 2.35 μF/cm², while Substrate B had a maximum capacitance of about 2.55 μF/cm².

### Example 10

### HfOₓ Deposition for FIGS. 6A-6B

A hafnium oxide layer was deposited on Substrates A, B and C under the identical process conditions. Substrate A was not exposed to the inert plasma process or the thermal annealing process. Substrates B and C were transferred into the DPN chamber and independently exposed to identical nitridation plasma process to densify and incorporate nitrogen atoms within the hafnium oxide layer to form a hafnium oxynitride material. The nitridation process contained an argon flow rate of about 160 sccm and a nitrogen flow rate of about 40 sccm for about 180 seconds at about 1,800 watts with a 50% duty cycle at 10 kHz. Substrate B was transferred to the thermal annealing chamber and heated at about 500° C. for about 15 seconds in an oxygen/nitrogen (about 0.1 vol %) atmosphere maintained at about 15 Torr. Substrate C was transferred to the thermal annealing chamber and heated at about 1,000° C. for about 15 seconds in an oxygen/nitrogen (about 0.1 vol %) atmosphere maintained at about 15 Torr.

The capacitance was measured on each surface to reveal Substrate C had a higher capacitance than Substrate B, that had a higher capacitance than Substrate A (FIG. 6A). Substrate A had a maximum capacitance of about 1.75 μF/cm², Substrate B had a maximum capacitance of about 1.95 μF/cm², while Substrate C had a maximum capacitance of about 2.35 μF/cm².

The current leakage was also measured on each surface to reveal Substrate C had a current density two magnitudes lower than both Substrates A and B (FIG. 6B). Substrates A and B each had a current density greater than about 100 A/cm², while Substrate C had a current density less than about 1 A/cm².

In one example, Table 1 illustrates that a substrate containing hafnium oxide not treated with a plasma process or an annealing process has a lower capacitance than a similar substrate exposed to such processes. Although two substrates were each exposed to a nitridation plasma process, the substrate exposed to a higher thermal annealing process (i.e., 1,000° C. as opposed to 500° C.) has a higher capacitance. Furthermore, although two substrates were each exposed to a thermal annealing process at about 1,000° C., the substrate exposed to an inert plasma process (e.g., containing argon) has a higher capacitance than the substrate exposed to a nitridation plasma process.

TABLE 1

| Experiment and | | Thermal Anneal | Capacitance |
|---|---|---|---|
| Substrate | Plasma Process | (° C.) | (μF/cm²) |
| Exp. 9 - Substrate A | nitrogen | 1,000 | 2.35 |
| Exp. 9 - Substrate B | argon | 1,000 | 2.55 |
| Exp. 10 - Substrate A | none | none | 1.75 |
| Exp. 10 -Substrate B | nitrogen | 500 | 1.95 |
| Exp. 10- Substrate C | nitrogen | 1,000 | 2.35 |

While the foregoing is directed to embodiments of the invention, other and further embodiments of the invention may be devised without departing from the basic scope thereof, and the scope thereof is determined by the claims that follow.

1. A method for forming a dielectric material on a substrate, comprising:
exposing a substrate sequentially to a metal-containing precursor and an oxidizing gas during an ALD process to form a metal oxide material thereon;
exposing the substrate to an inert plasma process; and
exposing the substrate to a thermal annealing process.

2. The method of claim 1, wherein the inert plasma process comprises an inert gas selected from the group consisting of argon, helium, neon and combinations thereof.

3. The method of claim 2, wherein the inert plasma process occurs for a time period within a range from about 30 seconds to about 5 minutes and at a power output within a range from about 500 watts to about 3,000 watts.

4. The method of claim 3, wherein the time period is within a range from about 1 minute to about 3 minutes and the power output is within a range from about 900 watts to about 1,800 watts.

5. The method of claim 2, wherein the inert plasma process comprises argon and is free of nitrogen or substantially free of nitrogen.

6. The method of claim 5, wherein the thermal annealing process occurs for a time period within a range from about 1 second to about 120 seconds and at a temperature within a range from about 600° C. to about 1,200° C.

7. The method of claim 6, wherein the time period is within a range from about 5 seconds to about 30 seconds and the temperature is within a range from about 800° C. to about 1,100° C.

8. The method of claim 6, wherein the thermal annealing process further comprises oxygen.

9. The method of claim 5, wherein the metal oxide material comprises at least one element selected from the group consisting of hafnium, tantalum, titanium, aluminum, zirconium, lanthanum and combinations thereof.

10. The method of claim 9, wherein the metal oxide material has a thickness within a range from about 5 Åto about 100 Å.

11. The method of claim 10, wherein the metal oxide material comprises hafnium oxide and the thickness is within a range from about 10 Å to about 60 Å.

12. The method of claim 10, wherein the metal oxide material has a capacitance of at least about 2.4 μF/cm².

13. The method of claim 9, wherein prior to forming the dielectric material, the substrate is exposed to a wet clean process to form an oxide layer with a thickness of about 10 Å or less.

14. The method of claim 13, wherein the substrate is exposed to a post deposition annealing process after the ALD process and prior to the inert plasma process.

15. A method for forming a dielectric material on a substrate, comprising:
positioning a substrate within a process chamber;
flowing a hydrogen source gas and an oxygen source gas into a water vapor generator to form an oxidizing gas comprising water vapor;
exposing the substrate sequentially to the oxidizing gas and at least one metal-containing precursor during an ALD process to form a dielectric material thereon;
exposing the substrate to an inert plasma process; and
exposing the substrate to a thermal annealing process.

16. The method of claim 15, wherein the at least one metal-containing precursor is selected from the group consisting of a hafnium precursor, a zirconium precursor, an aluminum precursor, a tantalum precursor, a titanium precursor, a lanthanum precursor and combinations thereof.

17. The method of claim 16, wherein the dielectric material comprises at least one material selected from the group consisting of hafnium oxide, zirconium oxide, lanthanum oxide, tantalum oxide, titanium oxide, aluminum oxide, derivatives thereof and combinations thereof.

18. The method of claim 17, wherein prior to forming the dielectric material, the substrate is exposed to a wet clean process to form an oxide layer with a thickness of about 10 Å or less.

19. The method of claim 15, wherein the inert plasma process comprises argon and is free of nitrogen or substantially free of nitrogen.

20. The method of claim 19, wherein the inert plasma process occurs for a time period within a range from about 1 minute to about 3 minutes and at a power output within a range from about 900 watts to about 1,800 watts.

21. The method of claim 19, wherein the thermal annealing process occurs for a time period within a range from about 5 seconds to about 30 seconds and at a temperature within a range from about 800° C. to about 1,100° C.

22. The method of claim 21, wherein the thermal annealing process further comprises oxygen.

23. The method of claim 17, wherein the dielectric material has a thickness within a range from about 5 Å to about 100 Å.

24. The method of claim 23, wherein the dielectric material comprises hafnium oxide and the thickness is within a range from about 10 Å to about 60 Å.

25. The method of claim 23, wherein the substrate is exposed to a post deposition annealing process after the ALD process and prior to the inert plasma process.

26. The method of claim 23, wherein the hafnium-containing material has a capacitance of at least about 2.4 μF/cm².

27. A method for forming a hafnium-containing material on a substrate, comprising:
exposing a substrate to a deposition process to form a dielectric material containing hafnium oxide thereon;
exposing the substrate to an inert plasma process that comprises argon and is free of nitrogen or substantially free of nitrogen; and
exposing the substrate to a thermal annealing process comprising oxygen.

28. The method of claim 27, wherein the hafnium-containing material has a capacitance of at least about 2.4 μF/cm².

29. The method of claim 27, wherein the deposition process to form the dielectric material is an ALD process comprising exposing the substrate sequentially to an oxidizing gas and a hafnium precursor to form the dielectric material containing hafnium oxide, wherein the oxidizing gas comprises water vapor and is formed by flowing a hydrogen source gas and an oxygen source gas into a water vapor generator.

30. A method for forming a dielectric material on a substrate, comprising:
exposing a substrate to a deposition process to form a metal oxide layer thereon;
exposing the substrate to a nitridation plasma process to form a metal oxynitride layer thereon; and
exposing the substrate to a thermal annealing process to form a dielectric material.

31. The method of claim 30, wherein the nitridation plasma process occurs for a time period within a range from about 1 minute to about 3 minutes and at a power output within a range from about 900 watts to about 1,800 watts.

32. The method of claim 31, wherein the nitridation plasma process comprises a process gas containing a nitrogen concentration of about 50 vol % or less.

33. The method of claim 32, wherein the dielectric material has a nitrogen concentration in a range from about 5 at % to about 25 at %.

34. The method of claim 33, wherein the metal oxide layer is substantially free of silicon.

35. The method of claim 30, wherein the metal oxide layer comprises at least one element selected from the group consisting of hafnium, tantalum, titanium, aluminum, zirconium, lanthanum and combinations thereof.

36. The method of claim 35, wherein the thermal annealing process occurs for a time period within a range from about 5 seconds to about 30 seconds and at a temperature within a range from about 800° C. to about 1,100° C.

37. The method of claim 36, wherein the thermal annealing process further comprises oxygen.

38. The method of claim 30, wherein the dielectric material has a thickness within a range from about 5 Å to about 100 Å.

39. The method of claim 38, wherein the dielectric material comprises hafnium oxynitride and the thickness is within a range from about 10 Å to about 60 Å.

40. The method of claim 39, wherein the dielectric material has a capacitance of at least about 2.4 μF/cm².

41. The method of claim 30, wherein the deposition process to form the metal oxide layer is an ALD process.

42. The method of claim 41, wherein prior to the ALD process, the substrate is exposed to a wet clean process to form an oxide layer with a thickness of about 10 Å or less.

43. The method of claim 42, wherein the substrate is exposed to a post deposition annealing process after the ALD process and prior to the nitridation plasma process.

44. The method of claim 41, wherein the ALD process comprises exposing the substrate sequentially to an oxidizing gas and at least one metal-containing precursor to form the metal oxide layer thereon.

45. The method of claim 44, wherein the oxidizing gas comprises water vapor and is formed by flowing a hydrogen source gas and an oxygen source gas into a water vapor generator.

46. The method of claim 45, wherein the at least one metal-containing precursor is selected from the group consisting of a hafnium precursor, a zirconium precursor, an aluminum precursor, a tantalum precursor, a titanium precursor, a lanthanum precursor and combinations thereof.

47. A method for forming a hafnium-containing material on a substrate, comprising:
exposing a substrate to a deposition process to form a dielectric material containing hafnium oxide thereon;
exposing the substrate to a nitridation plasma process to form hafnium oxynitride from the hafnium oxide; and
exposing the substrate to a thermal annealing process comprising oxygen.

48. The method of claim 47, wherein the hafnium-containing material has a capacitance of at least about 2.4 μF/cm².

49. The method of claim 47, wherein the deposition process to form the dielectric material is an ALD process comprising exposing the substrate sequentially to an oxidizing gas and a hafnium precursor to form the dielectric material containing hafnium oxide, wherein the oxidizing gas comprises water vapor and is formed by flowing a hydrogen source gas and an oxygen source gas into a water vapor generator.
